(19) United States
(12) Patent Application Publication
(10) Pub. No.: US 2025/0293180 A1
(43) Pub. Date: Sep. 18, 2025

(54) SEMICONDUCTOR STRUCTURE AND MANUFACTURING METHOD THEREOF

(71) Applicant: HON HAI PRECISION INDUSTRY CO., LTD., New Taipei City (TW)

(72) Inventors: Min-Cheng CHEN, Hsinchu City (TW); Tien-Fan OU, Hsinchu City (TW)

(21) Appl. No.: 18/646,797

(22) Filed: Apr. 26, 2024

(30) Foreign Application Priority Data
Mar. 18, 2024 (TW) 113110018

(51) Int. Cl. H01L 23/60; H01L 21/768; H01L 23/525

(52) U.S. Cl. CPC H01L 23/60; H01L 21/76886; H01L 23/5256

(57) ABSTRACT

A semiconductor structure includes a substrate, an active component, at least one discharge structure, a gate pad, a multi-layer interconnection metal layer, and a fuse structure. The substrate has an active area and a dummy area. The active component is disposed in the active area of the substrate. The discharge structure is disposed in the dummy area of the substrate. The gate pad is disposed above the active component and the discharge structure. The multi-layer interconnection metal layer is disposed above the substrate and disposed between the gate pad and the discharge structure and the gate pad, in which the active component is electrically connected to the gate pad through the multi-layer interconnection metal layer. The fuse structure has separate first and second portions, the first portion is connected to the multi-layer interconnection metal layer, and the second portion is connected to the discharge structure.

### CROSS-REFERENCE TO RELATED APPLICATION

This application claims priority to Taiwan Application Serial Number 113110018, filed Mar. 18, 2024, which is herein incorporated by reference in its entirety.

### BACKGROUND

### Field of Invention

The present disclosure relates to a semiconductor structure and a manufacturing method of the semiconductor structure. More particularly, the present disclosure relates to a semiconductor structure that prevents antenna effects and a manufacturing method thereof.

### Description of Related Art

Integrated circuits and other semiconductor devices are formed to include a multitude of individual transistors coupled together and to various other features to form functional devices. If any one of the transistors fails, device functionality can be destroyed. In advanced semiconductor device fabrication and manufacturing, plasma chemistry operations are typically used multiple times in the sequence of fabrication operations used to form virtually all integrated circuit and other semiconductor devices. Plasma operations include plasma etching operations and plasma deposition operations. Plasma vapor deposition, PVD, and plasma enhanced chemical vapor deposition, PECVD, represent just two of many plasma deposition operations.

The plasma operations utilize excited ions and these ions are typically directed to the surface substrate, often at high biases. The excited, accelerated ions of the plasma species can cause damage to the previously formed features. Reactive ion etch (RIE) operations and other operations that utilize ion bombardment, can also damage existing features and the damage caused to the existing features is often collectively referred to as plasma induced damage.

The highly sensitive transistors utilized in integrated circuits and other semiconductor devices, commonly include polysilicon or metal gates positioned over a gate dielectric which may be an oxide or other gate dielectric material. Plasma induced gate dielectric damage is commonly referred to as the antenna effect, and is an effect that damages transistor gates and the transistor gate dielectric materials and can potentially cause yield and reliability problems during the manufacture of MOS integrated circuits. Device functionality can be destroyed if the gate dielectric damage is severe. It would therefore be desirable and advantageous to provide structures that eliminate or alleviate any plasma induced gate dielectric damage.

### SUMMARY

One aspect of the present disclosure provides a semiconductor structure, which includes a substrate, an active component, at least one discharge structure, a gate pad, a multi-layer interconnection metal layer, and a fuse structure. The substrate has an active area and a dummy area. The active component is disposed in the active area of the substrate. The discharge structure is disposed in the dummy area of the substrate. The gate pad is disposed above the active component and the discharge structure. The multi-layer interconnection metal layer is disposed above the substrate and disposed between the gate pad and the discharge structure and the gate pad, in which the active component is electrically connected to the gate pad through the multi-layer interconnection metal layer. The fuse structure has separate first and second portions, the first portion is connected to the multi-layer interconnection metal layer, and the second portion is connected to the discharge structure.

Another aspect of the present disclosure provides a manufacturing method of a semiconductor structure, which includes the following steps. A substrate is provided, in which the substrate has an active area and a dummy area. An active component is formed in the active area of the substrate. At least one discharge structure is formed in the dummy area of the substrate. A fuse is formed and connected to the at least one discharge structure. A multi-layer interconnection metal layer is formed over the active component, the at least one discharge structure, and the fuse. A gate pad is formed over the multi-layer interconnection metal layer, in which the gate pad is electrically connected to the active component and the fuse through the multi-layer interconnection metal layer.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic top view illustrating a semiconductor structure according to one embodiment of the present disclosure.

FIG. 2 is a schematic cross-sectional view illustrating a semiconductor structure according to one embodiment of the present disclosure.

FIG. 3 is a schematic top view illustrating a certain process stage of manufacturing a semiconductor structure according to one embodiment of the present disclosure.

FIG. 4 is a schematic top view illustrating a certain process stage of manufacturing a semiconductor structure according to one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. Additionally, relative terms, such as “below” and “above,” may be used herein to describe one element's relationship to another element. It will be understood that relative terms are intended to encompass different orientations of the device in addition to the orientation illustrated in the figures. For example, if the device in one of the figures is turned over, elements described as “below” other elements would then be oriented “above” the other elements. Thus, the exemplary term “below” may include both “below” and “above” orientations, depending on the particular orientation of the drawing.

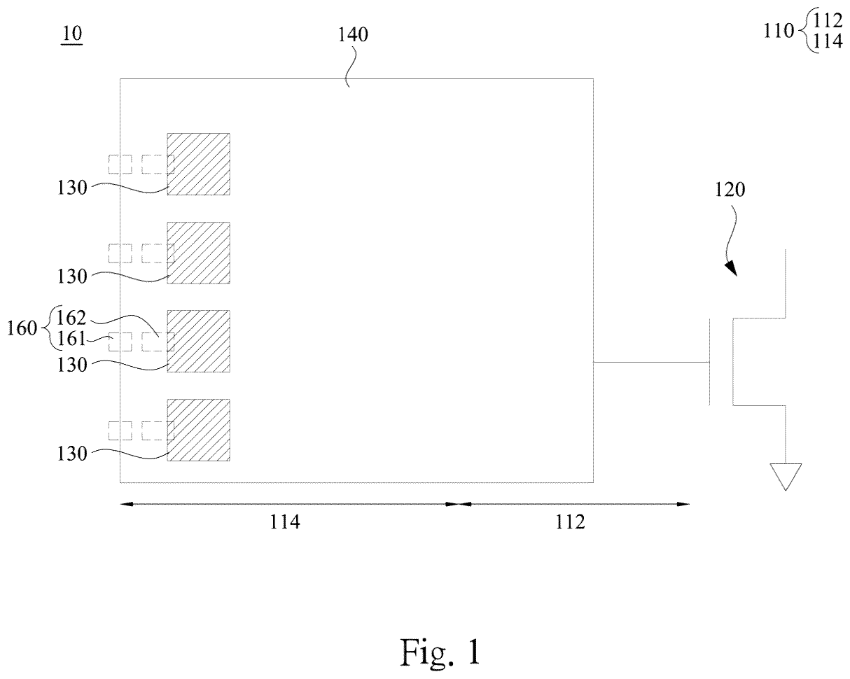

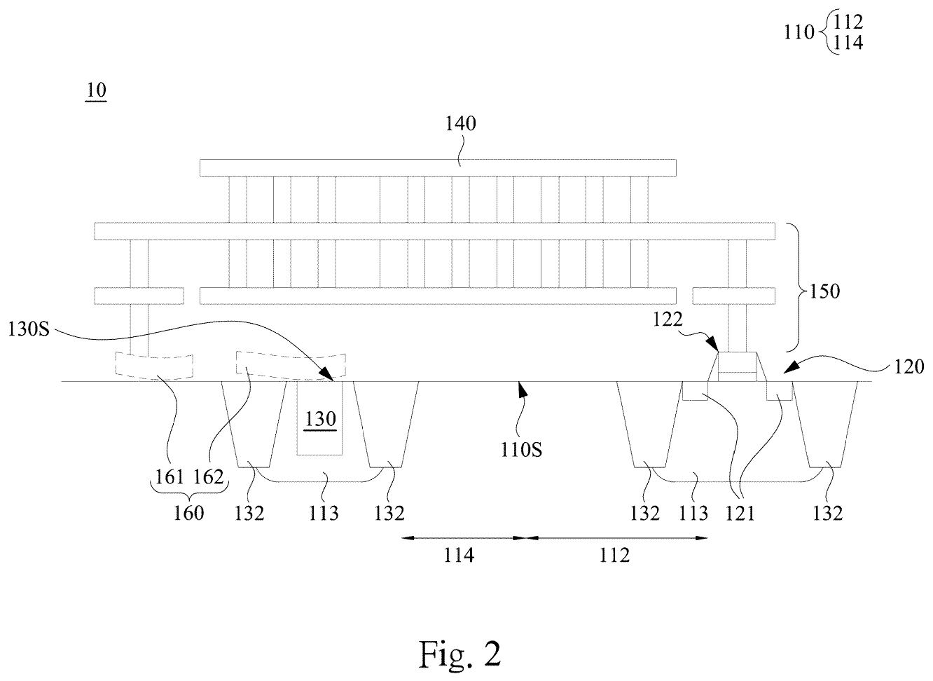

One aspect of the present disclosure is to provide a semiconductor structure, such as semiconductor structure 10 that may efficiently introduce charges generated during plasma processing into a substrate material. FIG. 1 is a schematic top view illustrating the semiconductor structure 10 according to one embodiment of the present disclosure. FIG. 2 is a schematic cross-sectional view illustrating the semiconductor structure 10 according to one embodiment of the present disclosure. Referring to FIG. 1 and FIG. 2 at the same time, the semiconductor structure 10 includes a substrate 110, an active component 120, at least one discharge structure 130, a gate pad 140, a multi-layer interconnection metal layer 150, and a fuse structure 160.

In some embodiments, the substrate 110 may include silicon substrate. In some alternative embodiments, the substrate 110 may be made of some other suitable elemental semiconductor (such as germanium or diamond), a suitable compound semiconductor (such as gallium arsenide, indium arsenide, indium phosphide, or silicon carbide), or a suitable alloy semiconductor (such as silicon germanium carbide, gallium indium phosphide or gallium arsenic phosphide). The substrate 110 may further include other features, such as various doped regions, a buried layer, and/or an epitaxial layer. Furthermore, the substrate 110 may be a semiconductor on insulator such as silicon on insulator (SOI) or silicon on sapphire (SOS). In some other embodiments, the substrate 110 may include a doped epitaxial layer, a gradient semiconductor layer, and/or may further include a semiconductor layer overlying another semiconductor layer of a different type, such as a silicon layer on a silicon germanium layer. In other examples, a compound semiconductor substrate may include a multilayer silicon structure or a silicon substrate may include a multilayer compound semiconductor structure. In one example, the substrate 110 includes doped wells 113 (such as n-wells and/or p-wells).

The active component 120 is disposed in the active area 112 of the substrate 110. In some embodiments, the active component 120 may be a field effect transistor, a bipolar transistor, a diode or the like, possibly in combination with respective passive circuit elements, such as resistors, capacitors and the like. Typically, any such circuit elements may be formed in the semiconductor structure 10 in accordance with certain design criteria on the basis of a specified process technique, such as CMOS techniques and the like, in order to form a specific integrated circuit of well-defined functionality. For convenience, from these many circuit elements that are typically present in the semiconductor structure 10, a transistor element is illustrated in FIG. 1 and FIG. 2, which may be provided in the form of a field effect transistor having an SOI architecture.

In the embodiment where the active component 120 is a transistor element, the transistor may represent a very thin semiconductor material, such as silicon material, silicon/germanium material, etc. It should be appreciated, however, that the principles disclosed herein, although providing specific operational advantages, as well as superior process control for sophisticated CMOS techniques, may be applied to any semiconductor device and manufacturing strategy in which plasma-induced charges need to be drained off during respective treatments on the basis of specifically designed protective structures, such as discharge structures and the like.

At least in generally advanced manufacturing stages of semiconductor structure 10, the transistor element may include at least a gate structure 122 above the substrate 110 and a source/drain region 121 having corresponding heavily doped and/or light-doped semiconductor materials. The source/drain region 121 may be disposed in the substrate 110. In some embodiments, the gate structure 122 may include a complex material system, such as a gate dielectric layer based on high-k dielectric materials, metal substances including barrier layers and electrode materials, etc.

In some embodiments, the insulating structure 132 may be formed in the substrate 110 isolate the various active components 120. The insulating structure 132 may utilize isolation technology, such as shallow trench isolation (STI) or local oxidation of silicon (LOCOS), to define and electrically isolate the various active components 120. In at least one embodiment, the insulating structure 132 is an STI. The insulating structure 132 may include silicon nitride, silicon oxide, silicon oxynitride, fluoride-doped silicate glass (FSG), a low-K dielectric material, other suitable materials, and/or combinations thereof.

The discharge structure 130 is disposed in the dummy area 114 of the substrate 110. In some embodiments, the discharge structure 130 is embedded in the substrate 110. In some embodiments, a top surface 130S of the discharge structure 130 is leveled with a surface 110S of the substrate 110. In some embodiments, the discharge structure 130 includes a metal conductive material, such as silver, aluminum, gold, copper, tin and/or alloys thereof. In some embodiments, a number of the discharge structure 130 is plural, and the discharge structures 130 are arranged in an array. In some embodiments, the discharge structures 130 may be metal pillars. The size of the discharge structure 130 would vary depending on the density and/or number of subsequent multi-layer interconnection metal layers.

The gate pad 140 is disposed over the active component 120 and the discharge structure 130. The gate pad 140 is used to electrically connect with the gate electrode of the active component 120 (i.e., the transistor). In some embodiments, a number of the discharge structure 130 is plural, and the discharge structures 130 are arranged at an interval in an orthographic projection of the gate pad 140 on the substrate 110. In some embodiments, a number of the discharge structure 130 is plural, and the discharge structures 130 are arranged along the edges of the gate pad 140.

The multi-layer interconnection metal layer 150 is disposed over the substrate 110 and disposed between the gate pad 140 and the discharge structure 130 and the active component 120. To be specific, the gate electrode in the active component 120 is electrically connected to the gate pad 140 through the multi-layer interconnection metal layer 150. In some embodiments, a number of the multi-layer interconnection metal layer 150 may be arranged according to actual requirements, such as one layer, two layers, three layers, four layers, or more layers.

The fuse structure 160 has a first portion 161 and a second portion 162 separated from each other. The first portion 161 is connected to the multi-layer interconnection metal layer 150, and the second portion 162 is connected to the discharge structure 130. In some embodiments, the fuse structure 160 is disposed on the substrate 110 and contacts the substrate 110. In some embodiments, the first portion 161 of the fuse structure 160 is in direct contact with the multi-layer interconnection metal layer 150, and the second portion 162 of the fuse structure 160 is in direct contact with the discharge structure 130. In some embodiments, the second portion 162 of the fuse structure 160 covers the top surface 130S of the discharge structure 130. It should be noted that the first portion 161 and the second portion 162 of the fuse structure 160 are in a disconnected state. In other words, the first portion 161 and the second portion 162 of the fuse structure 160 are electrically insulated. In the embodiment where the number of discharge structures 130 is plural, a number of the fuse structure 160 is also plural, and the number of the fuse structure 160 corresponds to the number of the discharge structure 130.

In some embodiments, a well 113 may be further included in the dummy area 114 of the substrate 110 and surrounds the discharge structure 130. The arrangement of the well 113 may provide a path for the discharge structure 130 to discharge to the substrate 110 more quickly.

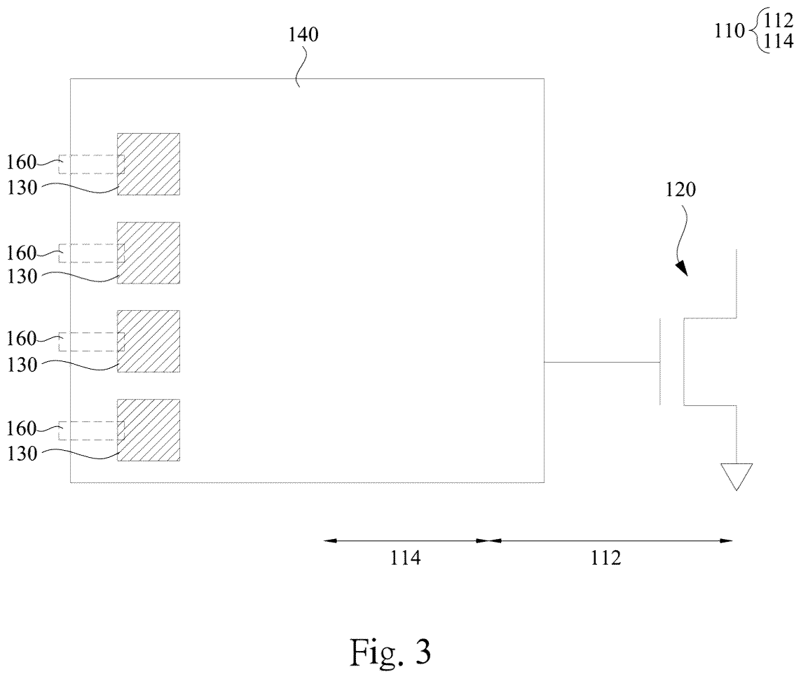

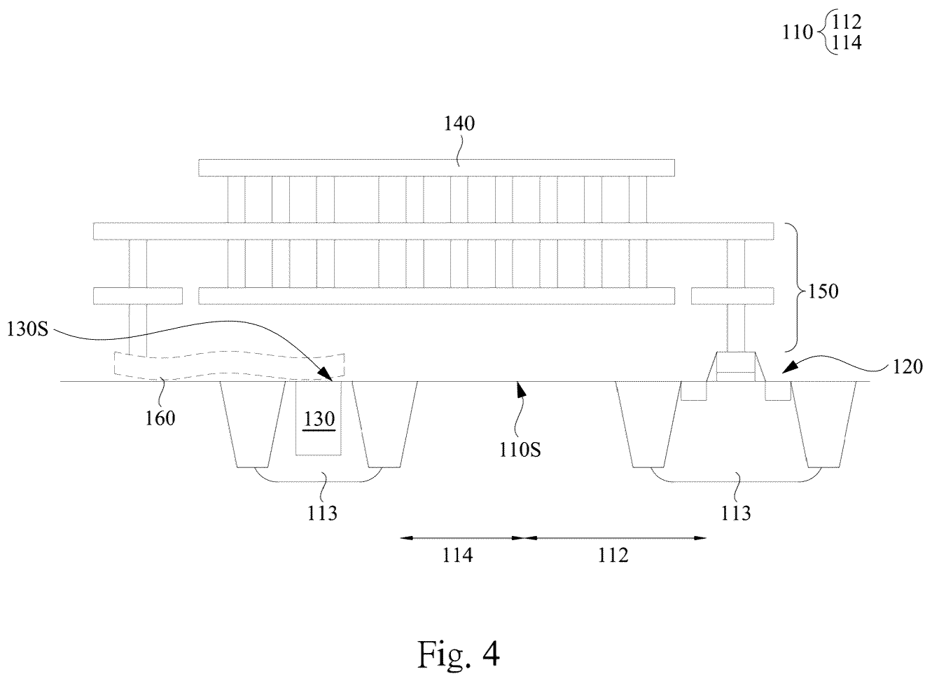

Another aspect of the present disclosure is to provide a manufacturing method of the semiconductor structure 10. FIG. 3 is a schematic top view illustrating a certain process stage of manufacturing the semiconductor structure 10 according to one embodiment of the present disclosure. FIG. 4 is a schematic top view illustrating a certain process stage of manufacturing the semiconductor structure 10 according to one embodiment of the present disclosure. First, a substrate 110 is provided. The substrate 110 has an active area 112 and a dummy area 114. An active component 120 is formed in the active area 112 of the substrate 110. For example, the active component 120 may be a transistor.

At least one discharge structure 130 is formed in the dummy area 114 of the substrate 110. It should be noted that the discharge structure 130 may be formed simultaneously with the active component 120 in the same process, or may be formed in different processes. In some embodiments, the discharge structure 130 is formed in the substrate 110. In some embodiments, a top surface 130S of the discharge structure 130 is leveled with a top surface 110S of the substrate 110. In some embodiments, the discharge structure 130 includes a metal conductive material, as described above. In some embodiments, a number of the discharge structure 130 is plural, and the discharge structures 130 are arranged in an array. In some embodiments, a well 113 is formed in the substrate 110, and the discharge structure 130 is formed in the well 113.

Referring to FIG. 3 and FIG. 4, the fuse 160 is formed to connect with the discharge structure 130. More specifically, the fuse 160 is in direct contact with the discharge structure 130. In some embodiments, the fuse 160 is formed directly on the substrate 110.

The multi-layer interconnection metal layer 150 is formed over the active component 120, the discharge structure 130, and the fuse 160. It should be noted that the discharge structure 130 and the fuse 160 need to be formed before the multi-layer interconnection metal layer 150 is formed. In some embodiments, a plasma process is used to form the multi-layer interconnection metal layer 150, and the charge in the plasma process is conducted out to the substrate 110 through the fuse 160 and the discharge structure 130, thereby preventing improper damage to the active component 120 in the active area 112. More specifically, when manufacturing the multi-layer interconnection metal layer 150 (e.g. during plasma etching process), charges accumulated during the process may be released to the ground (e.g. substrate 110) via the fuse 160 and the discharge structure 130.

The gate pad 140 is formed over the multi-layer interconnection metal layer 150, in which the gate pad 140 is electrically connected to the active component 120 and the fuse 160 through the multi-layer interconnection metal layer 150. In some embodiments, a number of the discharge structure 130 is plural, and the discharge structures 130 are arranged at an interval in an orthographic projection of the gate pad 140 on the substrate 110.

In some embodiments, the manufacturing method of the semiconductor structure 10 further includes a bias voltage is provided to the fuse 160 to blow the fuse 160, thereby obtaining the semiconductor structure 10 as shown in FIG. 1 and FIG. 2. It should be noted that since capacitance and/or leakage current are not part of the actual circuit design, the purpose of blowing the fuse 160 is to ensure that the gate pad 140 is electrically insulated from the ground when the semiconductor structure 10 is in normal operation. In other words, it is used to prevent current from being directed to the substrate 110 through the fuse 160 and the discharge structure 130. Additionally, the fuses may be suitably configured to enable the application of corresponding stimuli and/or current biases to blow the fuses 160 at any subsequent manufacturing stage, where the application of the individual stimuli may be performed at the wafer level or even in the packaged state of the corresponding semiconductor structure.

Given above, through the design of the fuse and discharge structure of the semiconductor structure disclosed in the present disclosure, critical areas with increased antenna effect during plasma treatments, such as gate electrode structures, drain and source regions of SOI transistor elements and the like, may be efficiently protected during the manufacturing process, and most of the corresponding areas (such as other active components located in the active area) may also be effectively protected. The fuse may then be disconnected at negligible capacitive coupling between the disconnected portions, significantly improving device performance due to reduced parasitic capacitance and/or leakage current. Therefore, the semiconductor structure design of the present disclosure has no additional conductive path load, and all protection structures (including fuses and discharge structures) are disposed in the dummy area below the gate pad.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a substrate having an active area and a dummy area;
an active component disposed in the active area of the substrate;
at least one discharge structure disposed in the dummy area of the substrate;
a gate pad disposed above the active component and the discharge structure;
a multi-layer interconnection metal layer disposed above the substrate and disposed between the gate pad and the discharge structure and the gate pad, wherein the active component is electrically connected to the gate pad through the multi-layer interconnection metal layer; and
a fuse structure having a first portion and a second portion separated from each other, wherein the first portion is connected to the multi-layer interconnection metal layer, and the second portion is connected to the discharge structure.

2. The semiconductor structure of claim 1, wherein the at least one discharge structure is embedded in the substrate.

3. The semiconductor structure of claim 2, wherein a top surface of the at least one discharge structure is leveled with a surface of the substrate.

4. The semiconductor structure of claim 1, wherein the at least one discharge structure comprises a metal conductive material.

5. The semiconductor structure of claim 1, wherein a number of the at least one discharge structure is plural, and the discharge structures are arranged at an interval in an orthographic projection of the gate pad on the substrate.

6. The semiconductor structure of claim 1, wherein a number of the at least one discharge structure is plural, and the discharge structures are arranged in an array.

7. The semiconductor structure of claim 1, wherein the second portion of the fuse structure is in direct contact with the at least one discharge structure.

8. The semiconductor structure of claim 1, wherein the fuse structure is disposed on the substrate.

9. The semiconductor structure of claim 1, further comprising a well disposed in the substrate, wherein the well surrounds the at least one discharge structure.

10. A manufacturing method of a semiconductor structure, comprising:
providing a substrate, wherein the substrate has an active area and a dummy area;
forming an active component in the active area of the substrate;
forming at least one discharge structure in the dummy area of the substrate;
forming a fuse connected to the at least one discharge structure;
forming a multi-layer interconnection metal layer over the active component, the at least one discharge structure, and the fuse; and
forming a gate pad over the multi-layer interconnection metal layer, wherein the gate pad is electrically connected to the active component and the fuse through the multi-layer interconnection metal layer.

11. The manufacturing method of the semiconductor structure of claim 10, further comprising:
providing a bias voltage to the fuse to blow the fuse.

12. The manufacturing method of the semiconductor structure of claim 10, wherein the at least one discharge structure is formed in the substrate.

13. The manufacturing method of the semiconductor structure of claim 12, wherein a top surface of the at least one discharge structure is leveled with a surface of the substrate.

14. The manufacturing method of the semiconductor structure of claim 10, wherein the at least one discharge structure comprises a metal conductive material.

15. The manufacturing method of the semiconductor structure of claim 10, wherein a number of the at least one discharge structure is plural, and the discharge structures are arranged at an interval in an orthographic projection of the gate pad on the substrate.

16. The manufacturing method of the semiconductor structure of claim 10, a number of the at least one discharge structure is plural, and the discharge structures are arranged in an array.

17. The manufacturing method of the semiconductor structure of claim 10, wherein the fuse is in direct contact with the at least one discharge structure.

18. The manufacturing method of the semiconductor structure of claim 10, wherein the fuse is formed on the substrate.

19. The manufacturing method of the semiconductor structure of claim 10, further comprising:
forming a well in the substrate, wherein the at least one discharge structure is formed in the well.

20. The manufacturing method of the semiconductor structure of claim 10, wherein the forming a multi-layer interconnection metal layer comprises performing a plasma process, and charges in the plasma process is conducted out of the substrate through the fuse and the at least one discharge structure.
